(19) United States
(12) Patent Application Publication
(10) Pub. No.: US 2008/0112134 A1
(43) Pub. Date: May 15, 2008

(54) Dust accumulation resistant heat sink

(76) Inventor: Brandon Rubenstein, Ft. Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/595,589

(22) Filed: Nov. 9, 2006

(51) Int. Cl. H05K 7/20

(52) U.S. Cl. 361/695

(57) ABSTRACT

A heat sink configured for cooling an integrated circuit comprises a plurality of fins arranged in substantially parallel planes and separated by a plurality of gaps. The parallel planes are adapted for usage in an arrangement parallel to an airflow direction and having a leading edge with respect to the airflow direction. The fin plurality is arranged with leading edge portions that extend at least two different lengths and nearest neighboring fins of the planar fin plurality extend different lengths.

### BACKGROUND

Cooling for a heat-generating semiconductor device such as computer chips can be implemented using a heat sink such as a high density, thin fin heat sink. Such heat sink types can quickly accumulate dust and become clogged, thereby no longer functioning efficiently.

Accumulation of dust on a heat sink, such as a typical thin fin heat sink 500 depicted in FIG. 5, occurs when the dust particles are caught on the leading edge 508 of the fins 502. Incoming dust particles then cling to particles already caught on the edge 508 and begin to build. Eventually, sufficient dust catches on adjacent leading edges 508 that new particles can bridge the gap between the fins and completely clog the air passage.

FIG. 6 is a perspective pictorial view showing dust 620 accumulated on the leading edges 608 of fins 602 of a thin fin, high density heat sink 600.

Dust accumulation has traditionally been address in several ways. A system can be designed so that even with a heavy load of dust, component temperatures remain within acceptable limits, leading to system over-design and elevated system cost. A dust filter can be included in a system, increasing maintenance management and cost through periodic service calls to change the filter, possibly increasing customer dissatisfaction. Heat sink edges can be manufactured, for example by machining or filing, to smooth fin edges, leading to more expensive manufacturing processes. Heat sinks can be designed with low fin density for more air passage, reducing heat sink efficiency and imposing a larger size specification for a heat sink for cooling a semiconductor component of a particular size and heat generation characteristics.

### SUMMARY

An embodiment of a heat sink configured for cooling an integrated circuit comprises a plurality of fins arranged in substantially parallel planes and separated by a plurality of gaps. The parallel planes are adapted for usage in an arrangement parallel to an airflow direction and having a leading edge with respect to the airflow direction. The fin plurality is arranged with leading edge portions that extend at least two different lengths and nearest neighboring fins of the planar fin plurality extend different lengths.

### BRIEF DESCRIPTION OF THE DRAWINGS

Embodiments of the invention relating to both structure and method of operation may best be understood by referring to the following description and accompanying drawings:

FIGS. 1A and 1B are perspective pictorial views showing an embodiment of a heat sink configured to increase cooling efficiency for an integrated circuit;

FIGS. 2A and 2B are perspective pictorial exploded and attached views that respectively depict an embodiment of an electronic system including a heat sink adapted for low dust accumulation;

FIGS. 3A and 3B are perspective pictorial views showing an embodiment of a heat sink configured to increase cooling efficiency for an integrated circuit using staggering of heat sink fins with more than two offsets;

FIGS. 4A and 4B are flow charts illustrating embodiments of methods for forming a heat sink configured for cooling an integrated circuit;

FIG. 5, labeled prior art, is a perspective pictorial view illustrating a typical thin fin heat sink; and

FIG. 6, labeled prior art, is a perspective pictorial view showing dust accumulated on the leading edges of fins of a thin fin, high density heat sink.

### DETAILED DESCRIPTION

An illustrative heat sink configuration and associated design technique enables reduction in the amount of dust that is accumulated on a heat sink.

The heat sink configuration and design technique reduce dust accumulation on a heat sink without compromising heat sink performance. The configuration and technique enable dust reduction and facilitate cooling performance even for challenging heat sink structures such as thin fin, high density heat sinks in which a large number of densely populated fins are included to substantially increase the convective surface area for semiconductor devices that generate a large amount of heat. The illustrative technique enables a relatively wide entry spacing of airflow into the fins in combination with tight fin spacing.

In various embodiments, a heat sink prevents dust particles from bridging the gap between fin edges by staggering the location of the leading edge of the fins, thereby widening the passage between fins for the dust to bridge. At a sufficiently large gap, airflow force can push the dust particles through the heat sink rather than allowing the particles to accumulate. The dust buildup is maintained at lower levels than would be experienced with a heat sink with an unstaggered or straight extension of leading edges.

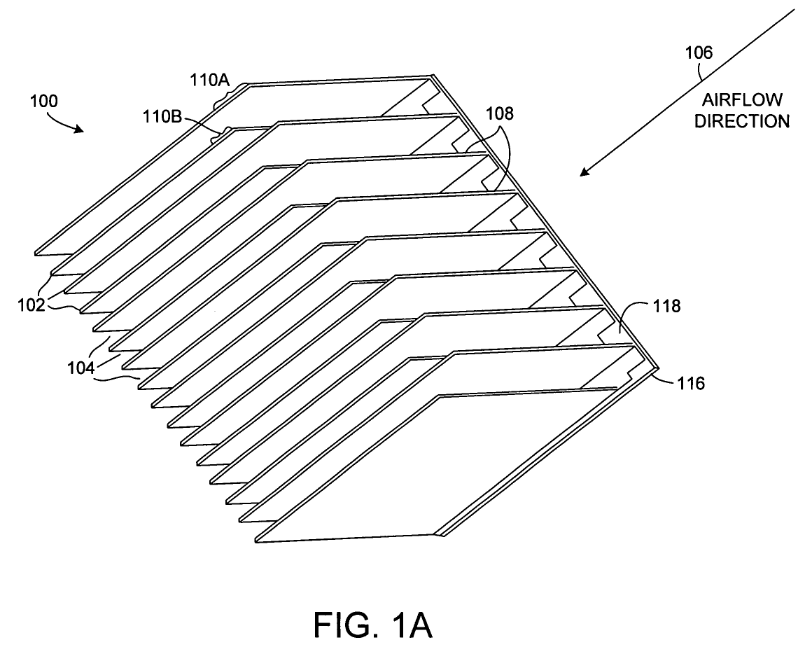

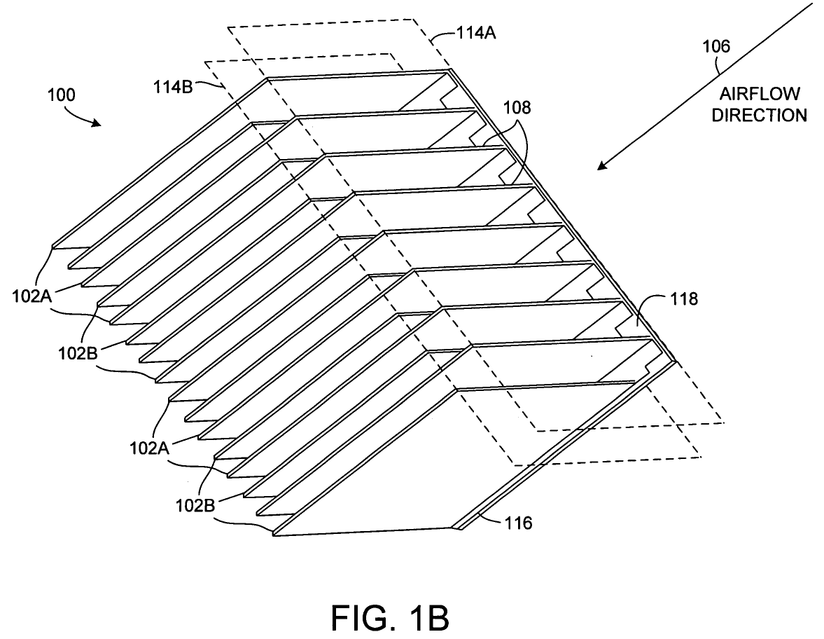

Referring to FIG. 1A, a perspective pictorial view shows an embodiment of a heat sink 100 configured to increase cooling efficiency for an integrated circuit. The heat sink 100 comprises a plurality of fins 102 arranged in substantially parallel planes and separated by a plurality of gaps 104. The parallel planes are adapted for usage in an arrangement substantially parallel to an airflow direction 106 and have a leading edge 108 with respect to the airflow direction 106. The multiple fins 102 are arranged with leading edge portions 108 that extend at least two different lengths 110A and 110B and alternate in length for nearest neighboring fins of the planar fin plurality.

The effective distance between the fins 102 at the leading edge 108 is increased and moved out of plane to make accumulation of heavy dust accumulation less likely, while maintaining a dense spacing of the fins 102.

In the context of the illustrative heat sink apparatus, the substantially parallel arrangement of the parallel planes with respect to the airflow direction 106 can be considered to include any arrangement within a 15° deviation from a precisely parallel arrangement.

Referring to FIG. 1B, the heat sink 100 comprises a first subset 102A of the fin plurality comprising fins with leading edges 108 aligned in a first plane 114A perpendicular to the airflow direction 106. The heat sink 100 further comprises a second subset 102B of the fin plurality comprising fins with leading edges aligned in a second plane 114B perpendicular to the airflow direction 106. The multiple fins 102A, 102B are configured in a staggered arrangement whereby first subset fins 102A alternate with second subset fins 102B lateral to the airflow direction 106.

In the illustrative embodiment, the first plane 114A and the second plane 114B are offset in the airflow direction 106 whereby distance between leading edges of nearest neighboring rows is increased to pass a selected dust particle size. In conditions typical in an electronic system, thin-fin high-density heat sinks tend to become clogged when the spacing between fins is smaller than approximately 4 millimeters. A more closely spaced fin arrangement may be desired to enable a suitable surface area for dissipating heat for electronic devices or components that generate a substantial heat amount. Accordingly, in an illustrative embodiment the gaps 104 between fins 102A, 102B may be smaller than 4 millimeters and the first 114A and second 114B planes offset so that the distance between leading edges 108 of neighboring fins is larger than 4 millimeters. Other embodiments may have gap distances and leading edge spacing optimized for larger or smaller dust particle sizes.

In an illustrative embodiment, the heat sink 100 can be configured as a thin-fin, high fin density heat sink wherein the multiple planar fins 102 are substantially uniform in thickness and gap thickness is less than approximately 4 millimeters.

In some embodiments, the illustrative offset or staggered leading edge planes can be implemented in combination with smoothing of the leading edges, for example by machining or filing, to further improve resistance to dust accumulation, although by incurring additional manufacturing costs.

The illustrative heat sink 100 further comprises a base plate 116 with a planar surface 118 configured for coupling to the multiple planar fins 102 in essentially a perpendicular attachment. The base plate 116 and the fins 102 are typically manufactured from a thermally conductive material.

For example, a thermally conductive base plate 116 can be configured for forming the multiple planar fins 102 in essentially a perpendicular attachment. The base plate 116 can further be configured for direct or convective thermal contact with a heat-generating electronic component.

In some embodiments, the base plate 116 can be sized either larger or smaller than the heat-generating electronic component according to the amount of heat generated by the component and configured for thermal contact with the component.

The illustrative heat sink 100 has multiple fins 102 comprising two-dimensional thin planar folded plate fins 102 arranged in multiple mutually parallel planes. In various embodiments, the multiple fins can be any suitable type of two-dimensional thin planar fins such as folded fins, stacked fins, cast fins, molded fins, and the like.

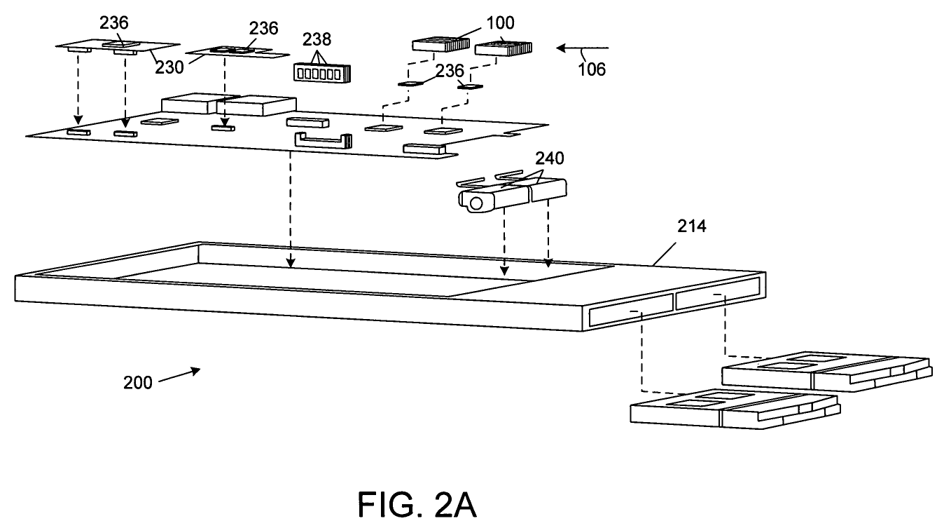

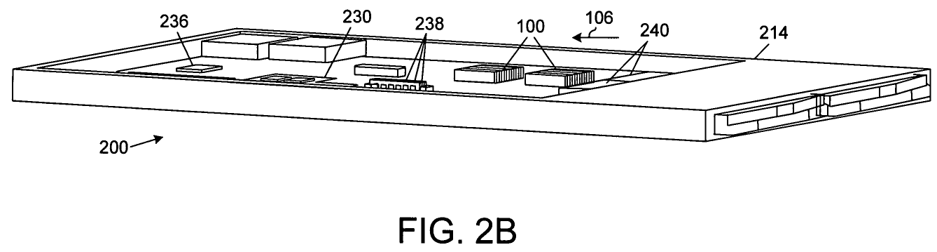

Referring to FIGS. 2A and 2B, perspective pictorial exploded and attached views depict an embodiment of an electronic system 200 including a heat sink 100 adapted for low dust accumulation. The electronic system 200 comprises a housing 214, a printed circuit board 230 mounted in the housing 214 and one or more heat-generating electronic semiconductor components 236, 238 coupled to the printed circuit board 230. The electronic system 200 further comprises an air mover 240 mounted within the housing 214 which is configured to generate airflow in an airflow direction 106. One or more heat sinks 100 are arranged in thermal contact with respective one or more of the heat-generating electronic semiconductor components 236, 238. As shown in FIGS. 1A and 1B, the heat sinks 100 are formed of multiple fins 102 arranged in substantially parallel planes, separated by gaps 104. The parallel planes are adapted for usage in an arrangement substantially parallel to an airflow direction 106 and have a leading edge 108 with respect to the airflow direction 106. The fins 102 are arranged with leading edge portions 108 that extend at least two different lengths 110A and 110B and alternate in length for nearest neighboring fins of the planar fins.

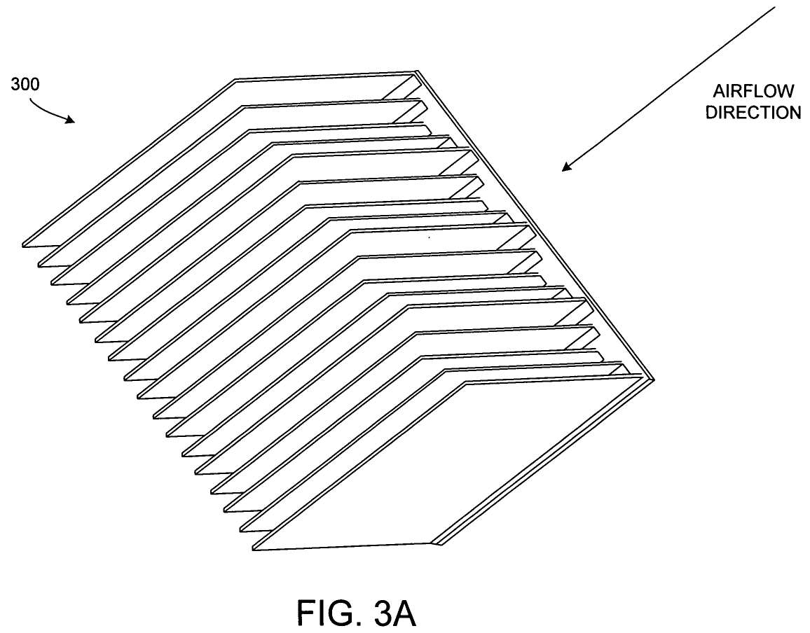

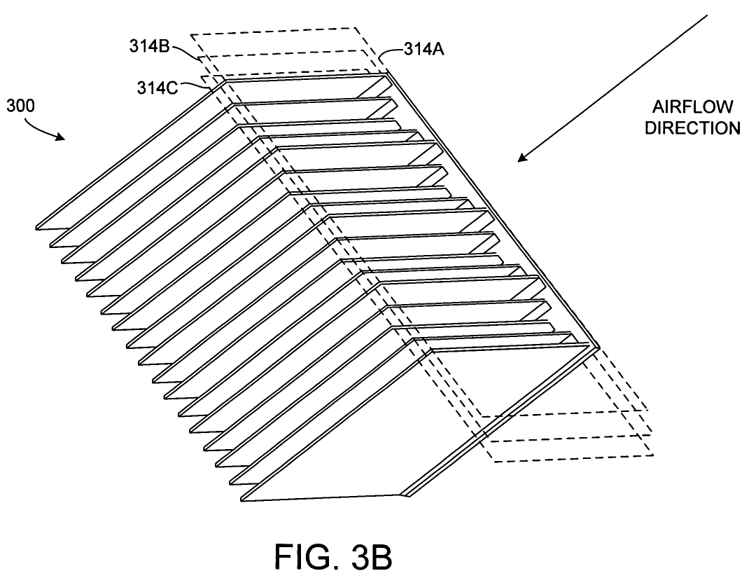

FIGS. 1A and 1B show heat sink arrangements with two offset planes 114A and 114B. In other embodiments, the leading edges can be aligned in more offset planes up to any suitable number of offset planes. Referring to FIGS. 3A and 3B, perspective pictorial views show an embodiment of a heat sink 300 that has three offset planes 314A, 314B, and 314C.

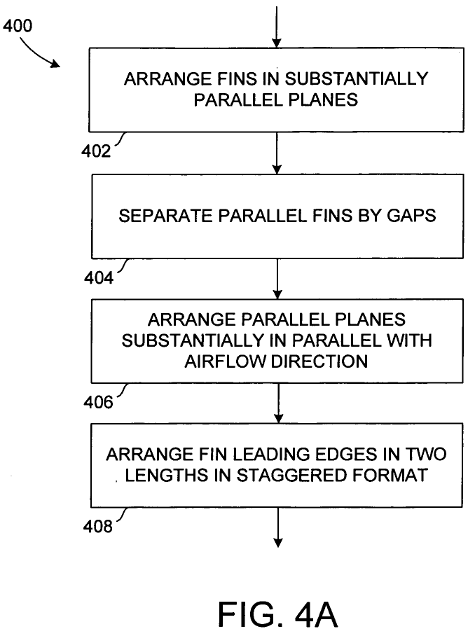

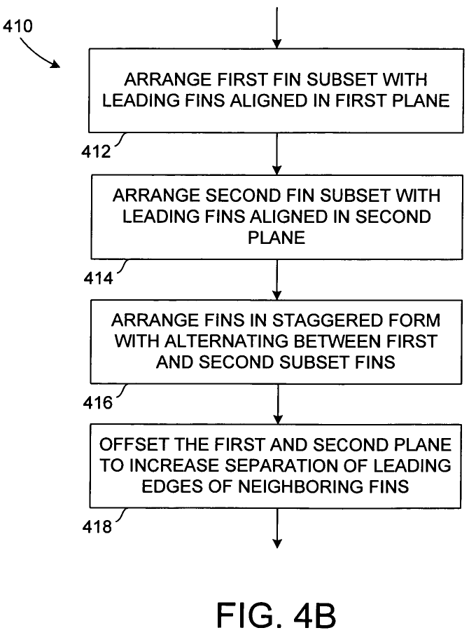

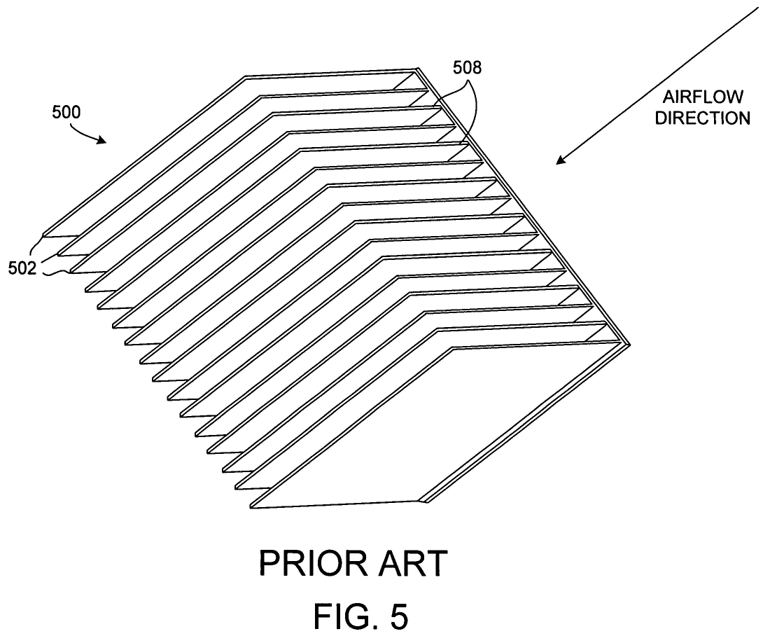

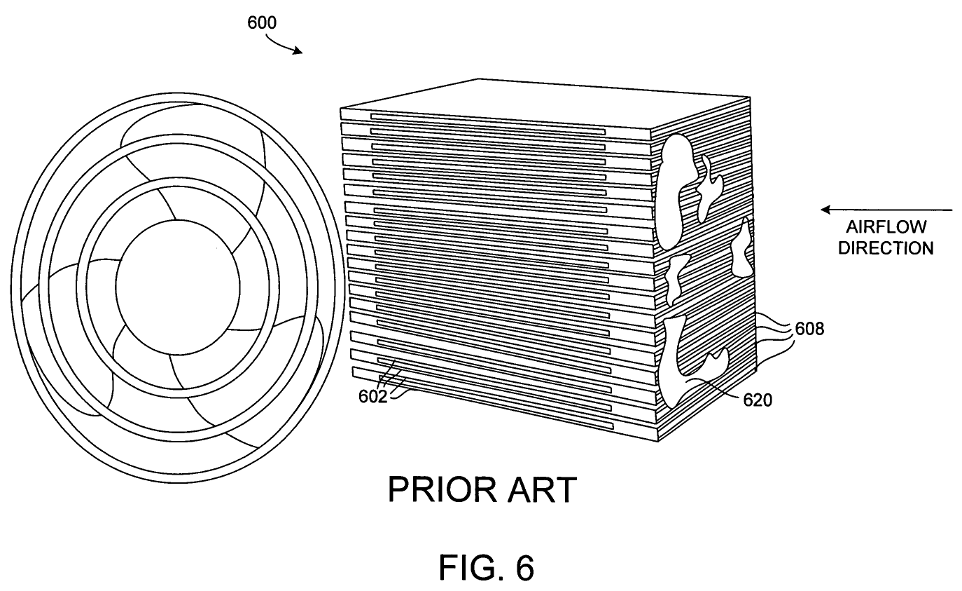

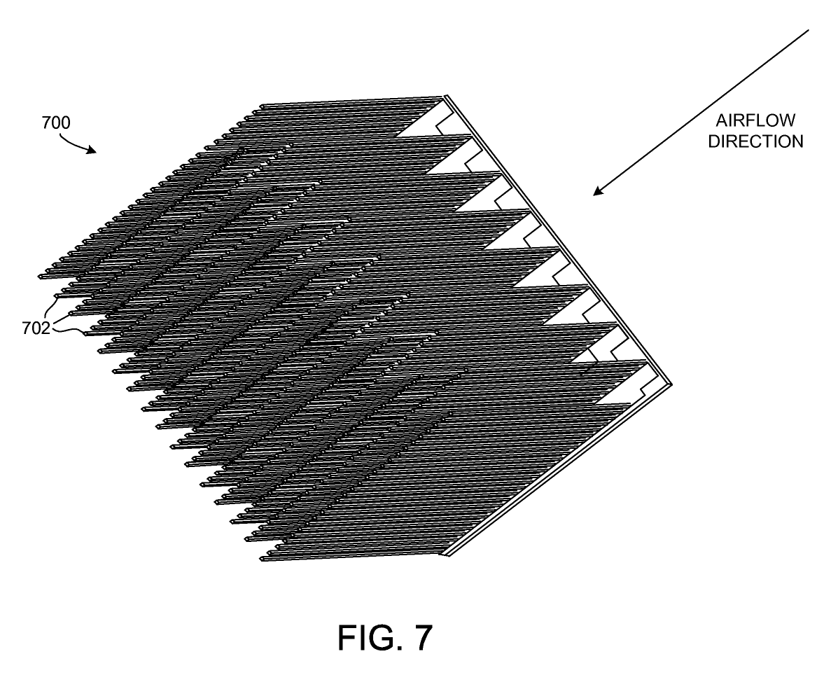

Referring to FIG. 4A, a flow chart illustrates an embodiment of a method 400 for forming a heat sink configured for cooling an integrated circuit. The method 400 comprises arranging 402 a plurality of fins in substantially parallel planes and separating 404 the fins by gaps. The parallel planes are arranged 406 substantially in parallel to an airflow direction with a leading edge with respect to the airflow direction. The fins are arranged 408 with leading edge portions that extend at least two different lengths and nearest neighboring fins of the planar fin plurality extend different lengths.

Referring to FIG. 4B, a flow chart illustrates a further embodiment of a method 410 for forming a heat sink. The method 410 comprises arranging 412 a first subset of the fins comprising fins with leading edges aligned in a first plane substantially perpendicular to the airflow direction and arranging 414 a second subset of the fins comprising fins with leading edges aligned in a second plane substantially perpendicular to the airflow direction. The fins are arranged 416 in a staggered arrangement whereby first subset fins alternate with second subset fins lateral to the airflow direction. The first plane and the second plane are offset 418 in the airflow direction whereby distance between leading edges of nearest neighboring rows is increased to pass a selected dust particle size.

In the context of the illustrative methods, the substantially parallel arrangement of the parallel planes with respect to the airflow direction can be considered to include any arrangement within 15° of a precisely parallel arrangement and the substantially perpendicular arrangement of the plane of the leading edges with the airflow direction can be considered to include any arrangement within a 15° deviation from a precisely perpendicular arrangement.

In the illustrative embodiments, the reduction of dust accumulation enables designs of smaller heat sinks, reducing the amount of printed circuit board space allocated for the heat sink and enabling higher density systems.

The illustrative structures and techniques also maintain reduction in heat sink thermal performance over time to a minimum, enabling designers to allocate less time for predicting thermal performance degradation and maintaining cooling of components for the product life.

The illustrative heat sink embodiments may also enable elimination of a system filter, reducing production costs and accelerating design cycles.

The depicted heat sinks and associated methods, by virtue of improvement in resistance to dust accumulation, also improve pressure drop performance by facilitating clear airflow, reducing costs associated with system air moving devices.

Terms “substantially”, “essentially”, or “approximately”, that may be used herein, relate to an industry-accepted tolerance to the corresponding term. Such an industry-accepted tolerance ranges from less than one percent to twenty percent and corresponds to, but is not limited to, component values, integrated circuit process variations, temperature variations, rise and fall times, and/or thermal noise. The term “coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. Inferred coupling, for example where one element is coupled to another element by inference, includes direct and indirect coupling between two elements in the same manner as “coupled”.

The various functions, processes, methods, and operations performed or executed by the system can be implemented as programs that are executable on various types of processors, controllers, central processing units, microprocessors, digital signal processors, state machines, programmable logic arrays, and the like. The programs can be stored on any computer-readable medium for use by or in connection with any computer-related system or method. A computer-readable medium is an electronic, magnetic, optical, or other physical device or means that can contain or store a computer program for use by or in connection with a computer-related system, method, process, or procedure. Programs can be embodied in a computer-readable medium for use by or in connection with an instruction execution system, device, component, element, or apparatus, such as a system based on a computer or processor, or other system that can fetch instructions from an instruction memory or storage of any appropriate type. A computer-readable medium can be any structure, device, component, product, or other means that can store, communicate, propagate, or transport the program for use by or in connection with the instruction execution system, apparatus, or device.

The illustrative block diagrams and flow charts depict process steps or blocks that may represent modules, segments, or portions of code that include one or more executable instructions for implementing specific logical functions or steps in the process. Although the particular examples illustrate specific process steps or acts, many alternative implementations are possible and commonly made by simple design choice. Acts and steps may be executed in different order from the specific description herein, based on considerations of function, purpose, conformance to standard, legacy structure, and the like.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims.

1. An apparatus comprising:
a heat sink configured for cooling an integrated circuit comprising:
a plurality of pins fins aligned in a plurality of mutually parallel planes and separated by a plurality of gaps, the parallel planes adapted for usage in an arrangement parallel to an airflow direction and having a leading edge with respect to the airflow direction; and
the pin fin plurality arranged with leading edge portions that extend at least two different distances in a direction parallel to the airflow direction and nearest neighboring fins of the planar fin plurality extend different distances.

2. The apparatus according to claim 1 further comprising:
a first subset of the pin fin plurality comprising pin fins with leading edges aligned in a first plane perpendicular to the airflow direction; and
a second subset of the pin fin plurality comprising pin fins with leading edges aligned in a second plane perpendicular to the airflow direction, the pin fin plurality configured in a staggered arrangement whereby first subset pin fins alternate with second subset pin fins lateral to the airflow direction.

3. The apparatus according to claim 2 further comprising:
the first plane and the second plane being offset in the airflow direction whereby distance between leading edges of nearest neighboring rows is increased to pass a selected dust particle size.

4. The apparatus according to claim 1 further comprising:
a base plate comprising a planar surface configured for coupling to the planar pin fin plurality in essentially a perpendicular attachment, the base plate and the pin fin plurality being manufactured from a thermally conductive material.

5. The apparatus according to claim 1 further comprising:
the heat sink configured as a thin-fin, high fin density heat sink wherein the planar fin plurality are substantially uniform in thickness and gap thickness is less than approximately 4 millimeters.

6. The apparatus according to claim 1 further comprising:
leading edges of the mutually parallel fin pin planes comprising edges smoothed by machining or filing.

7. The apparatus according to claim 1 further comprising:
the fin plurality comprising two-dimensional thin planar fins selected from a group consisting of folded fin, stacked fin, cast fin, and molded fin.

8. The apparatus according to claim 1 further comprising:
a thermally conductive base plate configured for forming the mutually planar pin fin plurality in essentially a perpendicular attachment, the base plate further configured for direct or convective thermal contact with a heat-generating electronic component.

9. The apparatus according to claim 1 further comprising:
a thermally conductive base plate configured for coupling to the planar fin plurality in essentially a perpendicular attachment, the base plate sized according to amount of heat generated by a heat-generating electronic component and configured for thermal contact with the component.

10. An electronic system comprising:
a housing;
a printed circuit board mounted in the housing;
at least one heat-generating electronic semiconductor component coupled to the printed circuit board;
an air mover mounted within the housing and configured to generate airflow in an airflow direction; and
at least one heat sink arranged in thermal contact with ones of the at least one heat-generating electronic semiconductor component comprising:
a plurality of pin fins aligned in a plurality of mutually parallel planes and separated by a plurality of gaps, the parallel planes adapted for usage in an arrangement parallel to an airflow direction and having a leading edge with respect to the airflow direction; and
the pin fin plurality arranged with leading edge portions that extend at least two different distances in a direction parallel to the airflow direction and nearest neighboring fins of the planar fin plurality extend different distances.

11. The electronic system according to claim 10 further comprising:
ones of the at least one heat sink comprising:
a first subset of the pin fin plurality comprising pin fins with leading edges aligned in a first plane perpendicular to the airflow direction; and
a second subset of the pin fin plurality comprising pin fins with leading edges aligned in a second plane perpendicular to the airflow direction, the pin fin plurality configured in a staggered arrangement whereby first subset pin fins alternate with second subset pin fins lateral to the airflow direction.

12. The electronic system according to claim 11 further comprising:
ones of the at least one heat sink comprising:
the first plane and the second plane being offset in the airflow direction whereby distance between leading edges of nearest neighboring rows is increased to pass a selected dust particle size.

13. The electronic system according to claim 10 further comprising:
ones of the at least one heat sink comprising:
a base plate comprising a planar surface configured for coupling to the planar pin fin plurality in essentially a perpendicular attachment, the base plate and the pin fin plurality being manufactured from a thermally conductive material.

14. The electronic system according to claim 10 further comprising:
ones of the at least one heat sink comprising:
the heat sink configured as a thin-fin, high fin density heat sink wherein the planar fin plurality are substantially uniform in thickness and gap thickness is less than approximately 4 millimeters.

15. The electronic system according to claim 10 further comprising:
ones of the at least one heat sink comprising:
leading edges of the mutually parallel fin pin planes comprising edges smoothed by machining or filing.

16. The electronic system according to claim 10 further comprising:
ones of the at least one heat sink comprising:
the fin plurality comprising two-dimensional thin planar fins selected from a group consisting of folded fin, stacked fin, cast fin, and molded fin.

17. The electronic system according to claim 10 further comprising:
ones of the at least one heat sink comprising:
a thermally conductive base plate configured for mounting the mutually planar pin fin plurality in essentially a perpendicular attachment, the base plate further configured for direct or convective thermal contact with a heat-generating electronic component.

18. The electronic system according to claim 10 further comprising:
ones of the at least one heat sink comprising:
a thermally conductive base plate configured for coupling to the planar fin plurality in essentially a perpendicular attachment, the base plate sized according to amount of heat generated by a heat-generating electronic component and configured for thermal contact with the component.

19. A method of forming a heat sink configured for cooling an integrated circuit comprising:
aligning a plurality of pin fins in a plurality of mutually parallel planes;
separating the pin fin plurality by a plurality of gaps;
arranging the mutually parallel planes substantially in parallel to an airflow direction with a leading edge with respect to the airflow direction; and
arranging the pin fin plurality with leading edge portions that extend at least two different distances in a direction parallel to the airflow direction and nearest neighboring fins of the planar fin plurality extend different distances.

20. The method according to claim 19 further comprising:
arranging a first subset of the pin fin plurality comprising fins with leading edges aligned in a first plane perpendicular to the airflow direction;
arranging a second subset of the pin fin plurality comprising fins with leading edges aligned in a second plane perpendicular to the airflow direction;
arranging the pin fin plurality in a staggered arrangement whereby first subset pin fins alternate with second subset pin fins lateral to the airflow direction; and
offsetting the first plane and the second plane in the airflow direction whereby distance between leading edges of nearest neighboring rows is increased to pass a selected dust particle size.
